(19) United States
(12) Patent Application Publication
(10) Pub. No.: US 2017/0336584 A1
(43) Pub. Date: Nov. 23, 2017

(54) FLEXIBLE SUBSTRATE AND OPTICAL MODULE

(71) Applicant: FURUKAWA ELECTRIC CO., LTD., Tokyo (JP)

(72) Inventors: Maiko ARIGA, Tokyo (JP); Etsuji KATAYAMA, Tokyo (JP); Toshio SUGAYA, Tokyo (JP)

(73) Assignee: FURUKAWA ELECTRIC CO., LTD., Tokyo (JP)

(21) Appl. No.: 15/673,484

(22) Filed: Aug. 10, 2017

Related U.S. Application Data
(63) Continuation of application No. PCT/JP2016/000688, filed on Feb. 10, 2016.

(30) Foreign Application Priority Data
Feb. 12, 2015 (JP) 2015-025828

(51) Int. Cl. G02B 6/42; H05K 1/11; H05K 1/02; G02B 6/27; H01S 5/0683; H01S 5/06

(52) U.S. Cl. CPC G02B 6/4281; H05K 1/028; G02B 6/2706; H05K 1/115; H01S 5/0612; H01S 5/06837; H05K 2201/10121

(57) ABSTRACT

A flexible substrate includes: an insulating base member; a plurality of lands formed aligned in a plurality of lines in a first direction on the base member; and a plurality of wirings formed on the base member, extending in a second direction intersecting the first direction, and connected to the plurality of lands on each line of the plurality of lines, wherein the plurality of wirings include a wiring extending between the lands aligned in the first direction, and wherein each of the plurality of lands has a planar shape longer in the second direction.

### CROSS-REFERENCES TO RELATED APPLICATIONS

This application is a continuation application of International Application No. PCT/JP2016/000688, filed Feb. 10, 2016, which claims the benefit of Japanese Patent Application No. 2015-025828, filed Feb. 12, 2015. The contents of the aforementioned applications are incorporated herein by reference in their entireties.

### FIELD

The present invention relates to a flexible substrate and an optical module in which the flexible substrate is mounted.

### BACKGROUND

Flexible substrates called flexible printed circuits (FPC) are widely used for configuring electric circuits in electronic devices. In a flexible substrate, wirings of a conductive layer such as a copper foil are formed on a flexible sheet-like base member such as a polyimide film material. The flexible substrate has a small thickness and can be deformed such as bent, warped, or the like. Thus, such a flexible substrate makes it possible to arrange a wiring in a space within an electronic device, arrange a wiring in a moving part, and arrange a wiring in a three-dimensional manner.

When a flexible substrate has two or more layers, through holes each having a circular cross section shape are provided as vias in the flexible substrate for electrically connecting different layers to each other. An inner wall of each through hole is plated with a metal such as Cu, for example. Further, through holes may be provided in a flexible substrate when the flexible substrate is connected to a component, an IC, an electronic circuit accommodated in a package with a lead pin, or the like. Around an opening of each through hole, a portion of an exposed wiring path called a land is provided. Each land is formed so as to have a complete-circular annular planar shape around the opening of a through hole. A land and a lead pin inserted in a through hole are electrically connected by soldering or the like. A related art are disclosed in Japanese Patent Application Publication No. 2005-340401.

In recent years, due to a demand for reduction in size of an electronic device, there is also a demand for reduction in size of a flexible substrate. To address this, it is necessary to densely form wirings in a flexible substrate. In the conventional lands, however, due to the planer shape thereof, it has been difficult to reduce a gap between neighboring wirings and densely form the wirings.

### SUMMARY

The present invention has been made in view of the above and intends to provide a flexible substrate that can realize densification of wirings and thereby realize reduction in size of the external form of the substrate and to provide an optical module in which such a flexible substrate in mounted.

According to an aspect of the present invention, provided is a flexible substrate having an insulating base member; a plurality of lands formed aligned in a plurality of lines in a first direction on the base member; and a plurality of wirings formed on the base member, extending in a second direction intersecting the first direction, and connected to the plurality of lands on each line of the plurality of lines, wherein the plurality of wirings include a wiring extending between the lands aligned in the first direction, and wherein each of the plurality of lands has a planar shape longer in the second direction.

According to another aspect of the present invention, provided is an optical module in which a flexible substrate is mounted, the optical module having a plurality of lead pins provided aligned in a plurality of lines, wherein the flexible substrate has an insulating base member; a plurality of lands formed aligned in a plurality of lines in a first direction on the base member, corresponding to the plurality of lead pins; and a plurality of wirings formed on the base member, extending in a second direction intersecting the first direction, and connected to the plurality of lands on each line of the plurality of lines, wherein the plurality of wirings include a wiring extending between the lands aligned in the first direction, wherein each of the plurality of lands has a planar shape longer in the second direction, wherein a plurality of vias are formed in the base member correspondingly to the plurality of lands, and wherein each of the plurality of lands is formed around an opening of corresponding one of the plurality of vias, and wherein each of the plurality of lead pins are inserted through corresponding one of the plurality of vias and fixed and electrically connected to corresponding one of the plurality of lands.

According to the present invention, densification of wirings in a flexible substrate can be realized. Therefore, according to the present invention, reduction in size of the external form of a flexible substrate can be realized.

### BRIEF DESCRIPTION OF DRAWINGS

FIG. 1 is a plan view illustrating a flexible substrate according to a first embodiment of the present invention.

FIG. 2 is an enlarged sectional view illustrating a state where a lead pin is fixed to the flexible substrate according to the first embodiment of the present invention.

FIG. 3A is a plan view illustrating an example of a land (part 1) in the flexible substrate according to the first embodiment of the present invention.

FIG. 3B is a plan view illustrating an example of a land (part 2) in the flexible substrate according to the first embodiment of the present invention.

FIG. 3C is a plan view illustrating an example of a land (part 3) in the flexible substrate according to the first embodiment of the present invention.

FIG. 3D is a plan view illustrating an example of a land (part 4) in the flexible substrate according to the first embodiment of the present invention.

FIG. 3E is a plan view illustrating an example of a land (part 5) in the flexible substrate according to the first embodiment of the present invention.

FIG. 3F is a plan view illustrating an example of a land (part 6) in the flexible substrate according to the first embodiment of the present invention.

FIG. 3G is a plan view illustrating an example of a land (part 7) in the flexible substrate according to the first embodiment of the present invention.

FIG. 4 is a plan view illustrating a flexible substrate according to a second embodiment of the present invention.

FIG. 5 is a plan view illustrating an optical module according to a third embodiment of the present invention.

FIG. 6 is a perspective view illustrating a transceiver device with the optical module according to the third embodiment.

### DESCRIPTION OF EMBODIMENTS

### First Embodiment

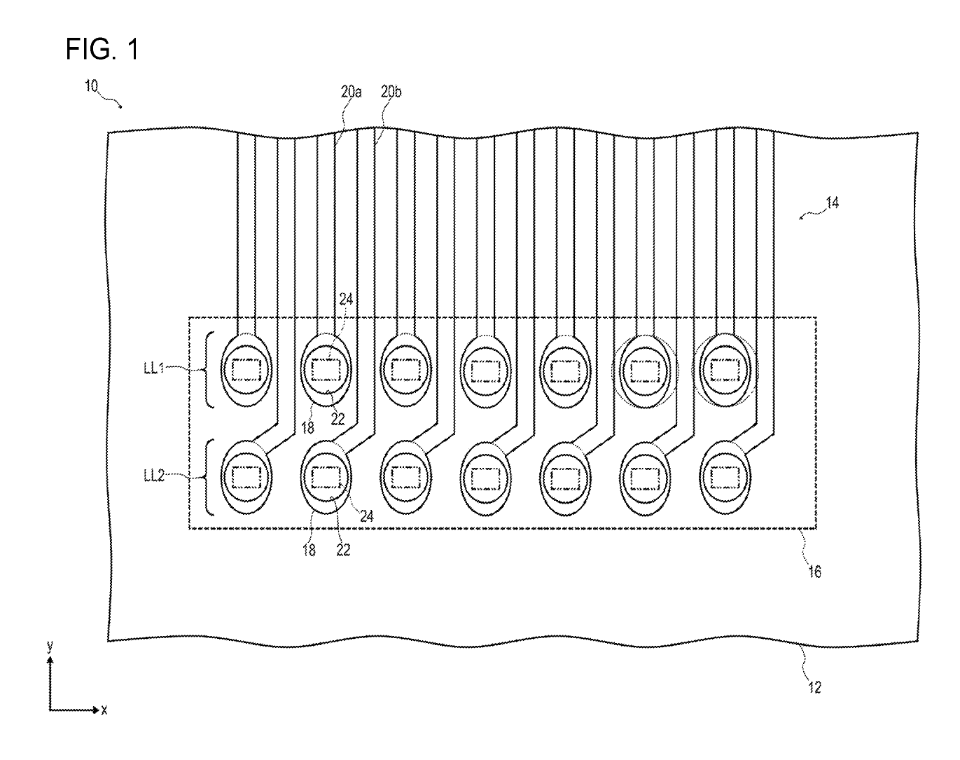

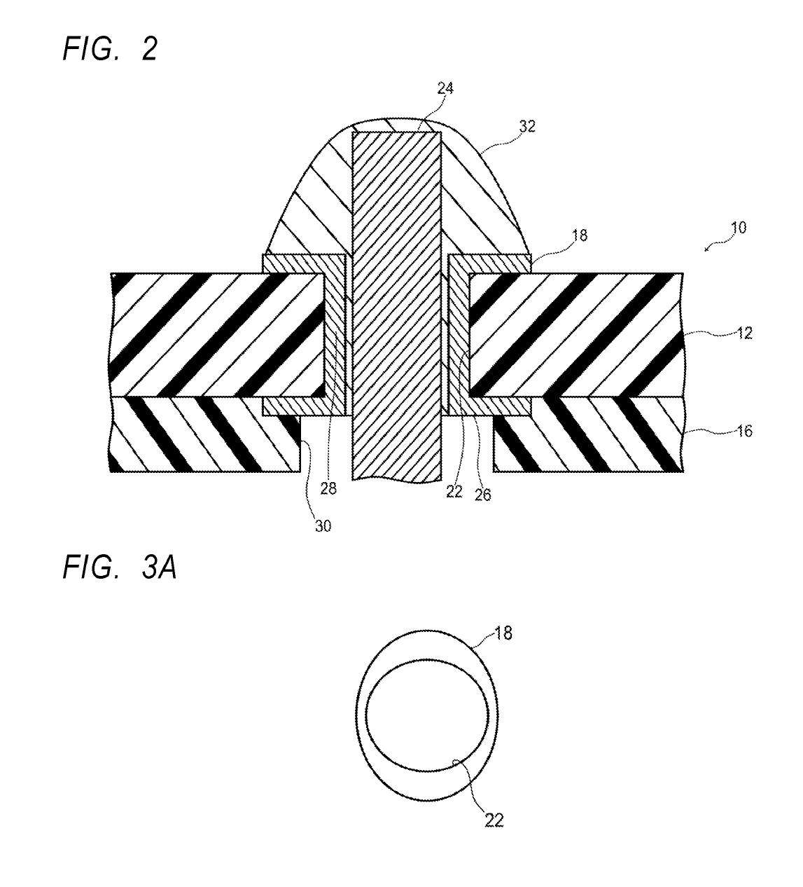

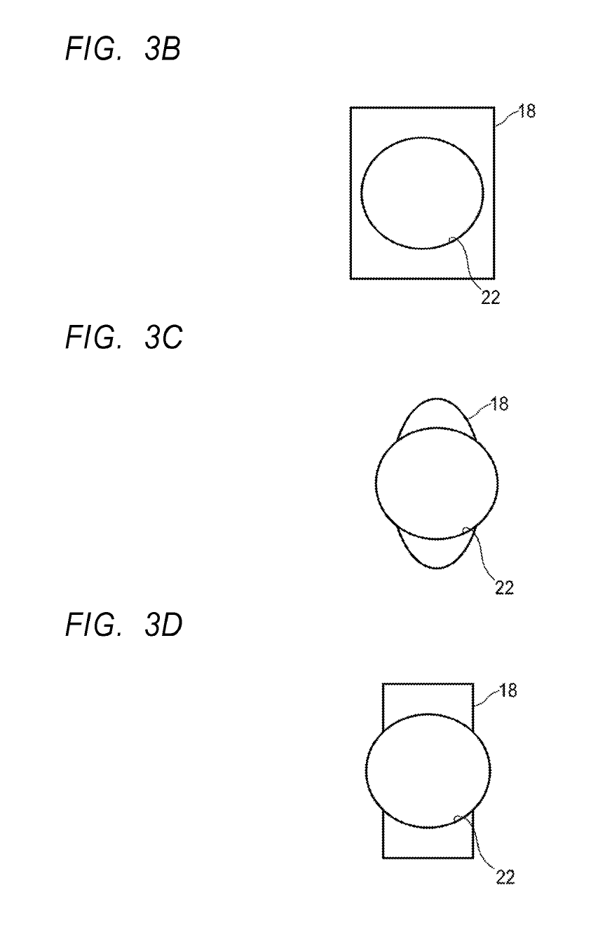

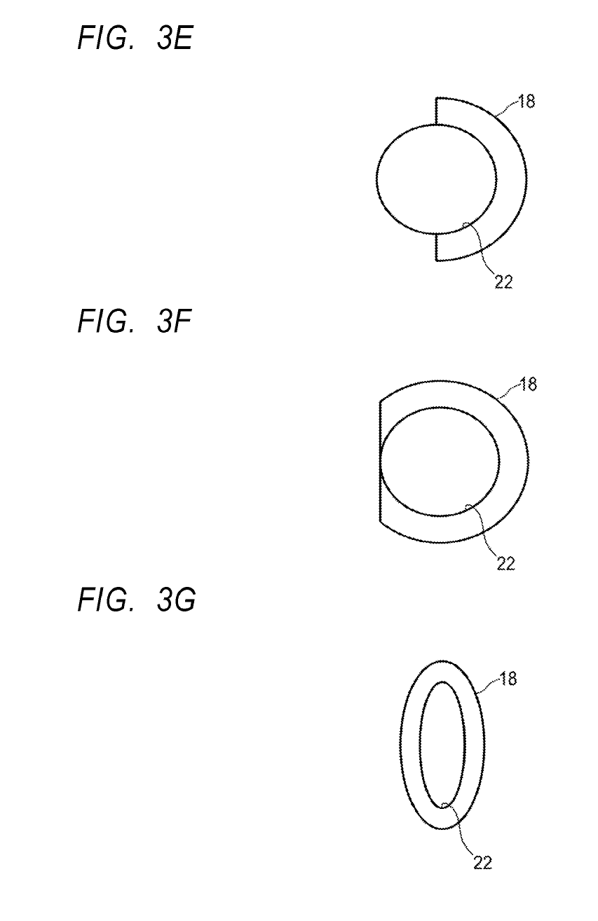

A flexible substrate according to the first embodiment of the present invention will be described by using FIG. 1 to FIG. 3G. FIG. 1 is a plan view illustrating a flexible substrate according to a first embodiment. FIG. 2 is an enlarged sectional view illustrating a state where a lead pin is fixed to the flexible substrate according to the present embodiment. FIG. 3A to FIG. 3G are plan views illustrating examples of a land in the flexible substrate according to the present embodiment.

As illustrated in FIG. 1, a flexible substrate 10 according to the present embodiment is an FPC, for example, and has a flexible sheet-like base member 12 and a wiring pattern 14 formed on one of the primary surfaces of the sheet-like base member 12. Furthermore, the flexible substrate 10 according to the present embodiment has a reinforcement plate 16 formed on the other primary surface of the sheet-like base member 12.

The sheet-like base member 12 is an insulating base member made of a film material such as a polyimide film material, for example. The sheet-like base member 12 has flexibility and softness. It is therefore possible to deform such as bend, warp, or the like the flexible substrate 10. While not limited in particular, the thickness of the sheet-like base member 12 may be 12 to 200 μm, for example.

The wiring pattern 14 formed on one primary surface of the sheet-like base member 12 has a plurality of lands 18, which are connection terminal portions, and a plurality of wirings 20a and 20b formed so as to be connected to the plurality of lands 18. The wiring pattern 14 is formed of a conductive layer of a conductive foil or the like such as a copper foil, for example. Note that a predetermined wiring pattern may be formed not only on one primary surface but also on the other primary surface of the sheet-like base member 12.

A plurality of through holes 22 are formed as vias in the sheet-like base member 12. The plurality of through holes 22 are formed aligned in two lines in the x-direction so as to form two lines of a first line LL1 and a second line LL2 in the x-direction. Each thorough hole 22 is formed so as to penetrate the sheet-like base member 12 from one primary surface to the other primary surface. The plurality of through holes 22 on the first line LL1 and the through holes 22 on the second line LL2 are arranged at the same pitch as each other and without displacement in the x-direction. Thus, the through hole 22 on the first line LL1 and the through hole 22 on the second line LL2 which are adjacent to each other are aligned in the y-direction orthogonal to the x-direction.

Each through hole 22 has a complete-circular cross section shape, for example. The diameter of the complete-circular cross section shape of each through hole 22 is not limited in particular and, depending on a machining method used for opening the through hole 22, or the like, may be 0.07 mm to 0.5 mm as a fine hole and may be 0.07 mm to 6 mm when including a middle-size hole, for example. Note that the through hole 22 can be opened by using drill machining, laser machining, chemical etching, plasma etching, or the like.

Further, while not limited in particular, the pitch in the x-direction of the through holes 22, that is, the distance between the centers of the through holes 22 adjacent in the x-direction may be less than or equal to 0.8 mm, for example, correspondingly to the wirings 20a and 20b densely formed as described later. Note that the under limit of this pitch may be 0.07 mm, for example, depending on a machining method used for opening the through holes 22, or the like.

The plurality of lands 18 are formed aligned in two lines in the x-direction so as to form two lines of the first line LL1 and the second line LL2 correspondingly to the plurality of through holes 22 on the first line LL1 and the second line LL2. The plurality of lands 18 on the first line LL1 and the plurality of lands 18 on the second line LL2 are arranged at the same pitch as each other and without displacement in the x-direction. Thus, the land 18 on the first line LL1 and the land 18 on the second line LL2 which are adjacent to each other are aligned in the y-direction orthogonal to the x-direction.

Each of the plurality of lands 18 is formed around the opening of the corresponding through hole 22. The pitch in the x-direction of the lands 18, that is, the distance between the centers of the lands 18 adjacent in the x-direction may be less than or equal to 0.8 mm, for example, similarly to the pitch in the x-direction of the through holes 22 described above, and the under limit thereof may be 0.3 mm, for example. The planar shape of each land 18 will be described later. Note that, while FIG. 1 depicts the case where fourteen lands 18 are formed such that seven lands 18 are formed on each of the first line LL1 and the second line LL2, the number of lands is not limited thereto. The number of the lands 18 is set depending on the number of electrical terminals such as lead pins to be fixed to the lands 18. For example, the number of the lands 18 may be greater than or equal to 50, and 25 or more lands may be formed on each of the first line LL1 and the second line LL2. The same applies to the number of the through holes 22 corresponding to the lands 18.

The wirings 20a are connected to the plurality of lands 18 on the first line LL1 from one side in the y-direction, respectively. Each wiring 20a extends in the y-direction and is connected to the corresponding land 18 on the first line LL1. The lands 18 and the wirings 20a connected thereto are formed of a conductive layer in an integral manner.

The wirings 20b extending in the y-direction in a similar manner are connected to the plurality of lands 18 on the second line LL2. Except the outermost wiring 20b, each wiring 20b is arranged so as to be located between the wirings 20a and between the lands 18 on the first line LL1, and each wiring 20a and each wiring 20b extend in the same direction on the sheet-like base member 12. Furthermore, each wiring 20b is bent toward the corresponding land 18 on the second line LL2 between the first line LL1 and the second line LL2 and connected to each corresponding land 18. The outermost wiring 20b is formed in a similar manner except that the outermost wiring 20b is not interposed between the wirings 20a and not interposed between the lands 18 on the first line LL1. The lands 18 and the wirings 20b connected thereto are formed by a conductive layer in an integral manner.

The wirings 20a and 20b are formed with the same wiring width as each other. While not limited in particular, the wiring width of the wirings 20a and 20b may be 0.04 to 0.1 mm, for example. Portions extending in the y-direction of the plurality of wirings 20a and the plurality of wirings 20b are arranged so as to be aligned in the x-direction at a regular pitch. While not limited in particular, this pitch of the wirings 20a and 20b in the x-direction, that is, the distance between the centers of the wirings 20a and 20b adjacent in the x-direction may be 0.1 to 0.5 mm, for example. As such, the wirings 20a and 20b are densely formed with a reduced pitch in the x-direction.

Each land 18 on the first line LL1 and the second line LL2 has a planar shape longer in the y-direction, which is the extending direction of the wirings 20a and 20b.

Specifically, each land 18 has an annular planar shape having an elliptical outer circumference with a longer axis in the y-direction and having a complete-circular inner circumference along a complete-circular opening of the corresponding through hole 22, for example, as illustrated in FIG. 1 and FIG. 3A. In a planar shape of each land 18, the center of the elliptical outer circumference matches the center of the complete-circular inner circumference.

While not limited in particular, the size of the planar shape of each land 18 can be set depending on the wiring width and the pitch or the like of the wirings 20a and 20b. Specifically, in the external form of the elliptical planar shape of the land 18, the length in the y-direction, that is, the length of the longer axis of the ellipse may be 0.15 to 0.3 mm, for example. Further, the width in the x-direction, that is, the length of the shorter axis of the ellipse may be 0.05 to 0.1 mm, for example.

The reinforcement plate 16 is fixed to a region on the other primary surface of the sheet-like base member 12 corresponding to a region on one primary surface of the sheet-like base member 12 where the plurality of lands 18 are formed. The reinforcement plate 16 is fixed to the sheet-like base member 12 via adhesion by using an adhesive agent or the like. The reinforcement plate 16 is provided for reinforcement to improve the strength of a region where the plurality of lands 18 are formed at which concentration of stress may occur when fixed. The reinforcement plate 16 has the outer circumference surrounding a region in which the plurality of lands 18 are formed. In the reinforcement plate 16, however, openings 30 (see FIG. 2) are formed so as to expose the openings of respective through holes 22 on the other primary surface side of the sheet-like base member 12.

While not limited to be made of a particular material, the reinforcement plate 16 may be made of glass un-woven fabric, glass fabric, or the like, for example. While not limited in particular, the thickness of the reinforcement plate 16 may be 100 μm or less, for example, in terms of ensuring flexibility of the flexible substrate 10. Note that the under limit of the thickness of the reinforcement plate 16 may be 5 μm, for example, in terms of improving the strength of a region in which the plurality of through holes 22 are formed.

A coverlay (not depicted) made of a resin or the like is formed on the sheet-like base member 12 on which the wiring pattern 14 is formed. Note that no coverlay is formed over regions of the sheet-like base member 12 on which the lands 18 are formed, and thus the lands 18 are exposed.

A lead pin 24, which is an external electrical terminal, is inserted through each through hole 22 where the land 18 is formed around the opening as described above. The lead pin 24 inserted through each through hole 22 is fixed and electrically connected to the land 18 by a conductive fixing member. The lead pin 24 electrically connected to the land 18 is provided to an optical module such as a semiconductor laser module, for example.

FIG. 2 is an enlarged sectional view illustrating the land 18, the lead pin 24, and the peripheral thereof with the lead pin 24 being fixed to the land 18. As depicted, the land 18 is formed around the opening of the through hole 22 on one primary surface of the sheet-like base member 12. A conductive layer 26 forming a wiring pattern is formed on the other primary surface. Further, a conductive layer 28 that electrically connects the land 18 to the conductive layer 26 is formed on the inner wall of the through hole 22. Further, the reinforcement plate 16 is fixed on the other primary surface of the sheet-like base member 12 correspondingly to a region in which the plurality of lands are formed. The opening 30 is formed in the reinforcement plate 16 so as to expose the opening of the through hole 22.

The corresponding lead pin 24 is inserted through the through hole 22. The lead pin 24 inserted through the through hole 22 is fixed and electrically connected to the land 18 by the conductive fixing member 32. For example, a solder, a brazing filler metal, or a conductive adhesive agent is used for the conductive fixing member 32.

Note that the flexible substrate 10 may be a double-sided flexible substrate in which conductive layers are formed on both primary surfaces of the sheet-like base member 12 as described above, or may be a single-sided flexible substrate in which a conductive layer is formed on one of the primary surfaces of the sheet-like base member 12. Further, the flexible substrate 10 may be a multilayer flexible substrate in which a plurality of conductive layers including three or more conductive layers are laminated.

One of the features of the flexible substrate 10 according to the present embodiment is that each of the plurality of lands 18 formed in two lines of the first line LL1 and the second line LL2 has a planar shape that is longer in the extending direction of the wirings 20a and 20b connected thereto.

Conventionally, a land on the flexible substrate is typically formed to have a complete-circular annular planar shape. The external forms of such conventional lands are depicted with thin dotted lines overlapped with the lands 18 which are the first and the second from the right on the first line LL1 in FIG. 1. As depicted, when the pitch in the x-direction of the wirings 20a and 20b is reduced, the conventional lands will overlap with the wiring 20b between the lands. It is therefore difficult to realize densification of wirings when the conventional lands are used.

In contrast, in the flexible substrate 10 according to the present embodiment, since each land 18 has a planar shape longer in the extending direction of the wirings 20a and 20b, the lands 18 can be densely formed. Therefore, overlap of the land 18 with the wiring 20b can be avoided even when the pitch in the x-direction of the wirings 20a and 20b is narrow. Thus, according to the present embodiment, the wirings 20a and 20b can be formed at a narrow pitch, and densification of wirings can be realized. Realizing densification of wirings in such a way allows for a reduction in the size of the substrate's external form of a flexible substrate.

Further, because the wirings 20a and 20b are densely formed, the lands 18 and the through holes 22 corresponding thereto are also densely formed. Even when the through holes 22 are densely formed in such a way, the reinforcement plate 16, which has the outer circumference surrounding a region in which the plurality of lands 18 are formed and includes the region in which the plurality of lands 18 are formed, is provided to the sheet-like base member 12, as described above. With such the reinforcement plate 16, it is possible to suppress a reduction in the strength of the flexible substrate 10 due to dense formation of the through holes 22 and therefore ensure the strength of the flexible substrate 10.

Note that, with respect to the external form of the planar shape of the land 18 that is longer in the extending direction of the wirings 20a and 20b, it is preferable that the length in the extending direction of the wirings 20a and 20b be greater than or equal to 1.5 times the width in a direction orthogonal to the extending direction of the wirings 20a and 20b. This allows for sufficient densification of wirings. However, in order to ensure electrical connection of electrical terminal such as a lead pin to the land 18 by using the fixing member 32, it is preferable that the length in the extending direction of the wirings 20a and 20b be less than or equal to five times the width in a direction orthogonal to the extending direction of the wirings 20a and 20b.

Further, the planar shape of each land 18 may be any shape as long as it has a planar shape longer in the y-direction, which is the extending direction of the wirings 20a and 20b, without being limited to the annular planar shape having the elliptical outer circumference and having the complete-circular inner circumference as depicted in FIG. 1 and FIG. 3A. Other examples of a planar shape of the land 18 will be illustrated in FIG. 3B to FIG. 3G.

For example, as illustrated in FIG. 3B, the land 18 may have an annular planar shape having a rectangular outer circumference whose longitudinal direction is in the extending direction of the wirings 20a and 20b and having a complete-circular inner circumference along the complete-circular opening of the through hole 22. In the planar shape of the land 18, the center of the rectangular outer circumference matches the center of the complete-circular inner circumference.

Further, as illustrated in FIG. 3C and FIG. 3D, the land 18 may be formed separated in one side and the other side in the extending direction of the wirings 20a and 20b with respect to the complete-circular opening of the through hole 22.

The land 18 illustrated in FIG. 3C has a planar shape of an ellipse except a portion overlapping with the through hole 22 in which the ellipse has the same center as the center of the complete-circular opening of the through hole 22, has a longer axis in the extending direction of the wirings 20a and 20b, and has a shorter axis shorter than the diameter of the opening of the through hole 22.

The land 18 illustrated in FIG. 3D has a planar shape of a rectangle except a portion overlapping with the through hole 22 in which the rectangle has the same center as the center of the complete-circular opening of the through hole 22, has a longitudinal direction in the extending direction of the wirings 20a and 20b, and has a width in the short direction narrower than the diameter of the opening of the through hole 22.

Further, as illustrated in FIG. 3E and FIG. 3F, the land 18 may have a planar shape longer in the extending direction of the wirings 20a and 20b with a part of the complete-circular annular planar shape being cut off.

The land 18 illustrated in FIG. 3E has a planar shape in which, from the complete-circular annular planar shape arranged around the opening of the through hole 22, one side part is cut off along the center line as a border that runs in the extending direction of the wirings 20a and 20b.

Further, the land 18 illustrated in FIG. 3F has a planar shape in which, from the complete-circular annular planar shape arranged around the opening of the through hole 22, the smaller area portion is cut off along a tangent as a border that contacts with the through hole 22 and runs in the extending direction of the wirings 20a and 20b.

Further, the through hole 22 may have a cross section shape longer in the y-direction, which is the extending direction of the wirings 20a and 20b, without being limited to have a complete-circular cross section shape.

For example, as illustrated in FIG. 3G, the through hole 22 may have an elliptical cross section shape having a longer axis in the extending direction of the wirings 20a and 20b. In this case, the land 18 may have an elliptical annular planar shape along the elliptical opening of the through hole 22.

Note that, since machining of the through hole 22 having a complete-circular cross section shape is relatively easy, the through hole 22 having a complete-circular cross section shape can be formed with a smaller size than a through hole having a cross section shape other than a complete-circular cross section shape, such as an elliptical cross section shape. It is therefore preferable that the through hole 22 have a complete-circular cross section shape.

### Second Embodiment

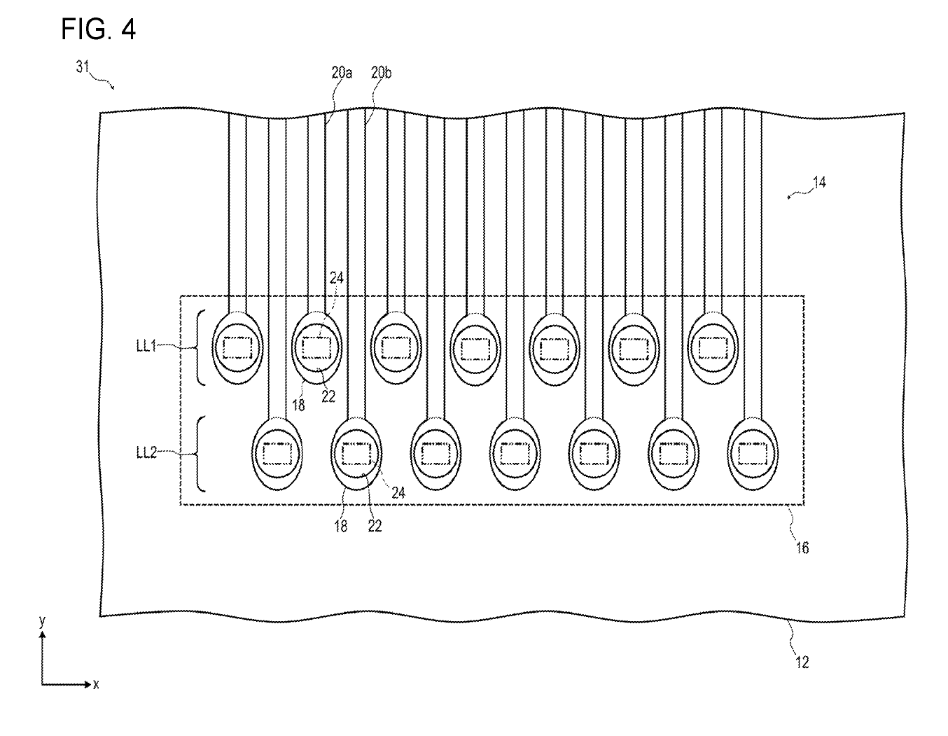

A flexible substrate according to the second embodiment of the present invention will be described by using FIG. 4. FIG. 4 is a plan view illustrating a flexible substrate according to the present embodiment. Note that components similar to those of the flexible substrate according to the above-described first embodiment are labeled with the same reference numerals, and description thereof will be omitted or simplified.

In the first embodiment described above, the case where the plurality of through holes 22 on the first line LL1 and the plurality of through holes 22 on the second line LL2 are arranged at the same pitch as each other without being displaced in the x-direction has been described. However, the form in which the plurality of through holes 22 and the plurality of corresponding lands 18 are arranged is not limited to the above. In the present embodiment, a case where the plurality of through holes 22 and the plurality of corresponding lands 18 are arranged in a staggered manner in two lines of the first line LL1 and the second line LL2 will be described.

As illustrated in FIG. 4, in a flexible substrate 31 according to the present embodiment, the plurality of through holes 22 are formed aligned in two lines in the x-direction so as to form two lines of the first line LL1 and the second line LL2 in the x-direction. The plurality of through holes 22 on the first line LL1 and the plurality of through holes 22 on the second line LL2 are arranged at the same pitch as each other shifted by half the pitch in the x-direction. In such a way, the plurality of through holes 22 are arranged in a staggered manner in two lines of the first line L11 and the second line LL2. Therefore, each of the through holes 22 on the second line LL2 is located at the center of the gap between the through holes 22 on the first line LL1 in the x-direction.

The plurality of lands 18 are formed aligned in two lines in the x-direction so as to form two lines of the first line LL1 and the second line LL2 correspondingly to the plurality of through holes 22 on the first line LL1 and the plurality of through holes 22 on the second line LL2. The plurality of lands 18 on the first line LL1 and the plurality of lands 18 on the second line LL2 are arranged at the same pitch as each other shifted by half the pitch in the x-direction. In such a way, the plurality of lands 18 are arranged in a staggered manner in two lines of the first line L11 and the second line LL2. Therefore, each of the lands 18 on the second line LL2 is located at the center of the gap between the lands 18 on the first line LL1 in the x-direction.

The wirings 20a are connected to the plurality of lands 18 on the first line LL1 from one side in the y-direction, respectively, in a similar manner to the first embodiment. Each wiring 20a extends in the y-direction and is connected to the corresponding land 18 on the first line L11 in a similar manner to the first embodiment.

The wirings 20b similarly extending in the y-direction are connected to the plurality of lands 18 on the second line LL2, respectively. Unlike the first embodiment, each of the wirings 20b is arranged so as to be located between the wirings 20a and between the lands 18 on the first line LL1 and connected to the corresponding land 18 on the second line LL2 without being bent.

As described above, the plurality of through holes 22 and the plurality of corresponding lands 18 may be arranged in a staggered manner in two lines of the first line LL1 and the second line LL2. Note that, since the present embodiment is similar to the first embodiment except the feature regarding the lands 18 and the corresponding wirings 20b described above, duplicated description is omitted.

### Third Embodiment

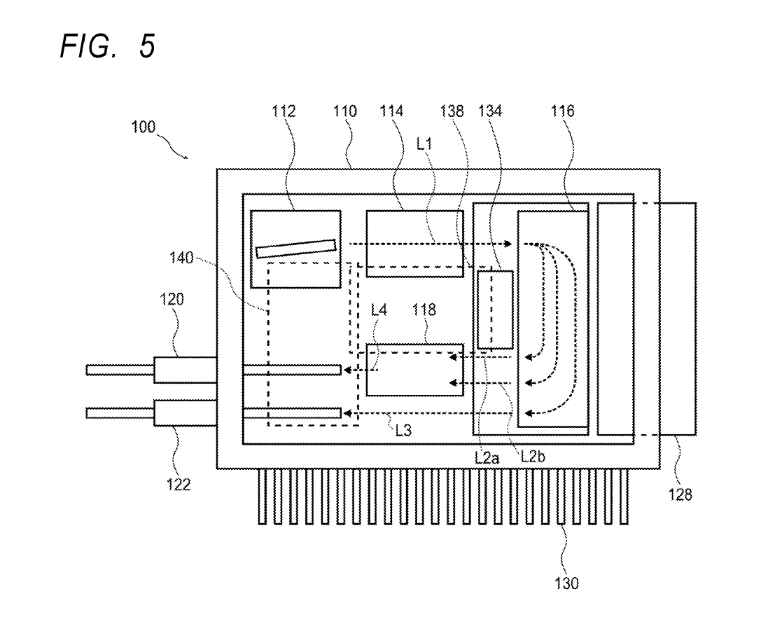

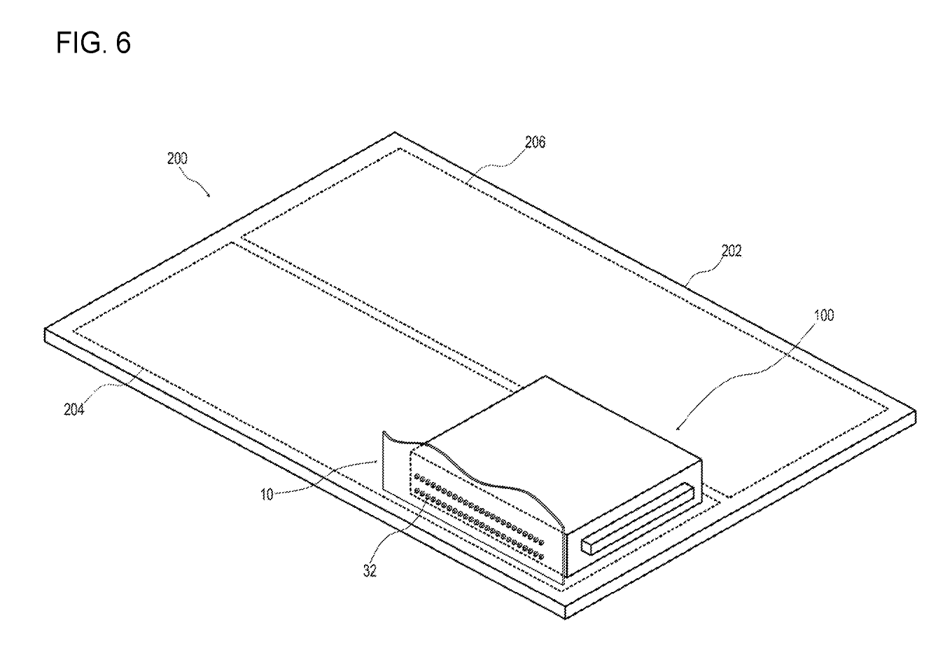

An optical module according to the third embodiment of the present embodiment will be described by using FIG. 5 and FIG. 6. FIG. 5 is a plan view illustrating the optical module according to the present embodiment. FIG. 6 is a perspective view illustrating a transceiver device with the optical module according to the present embodiment. Note that components similar to those of the flexible substrates according to the above-described first and second embodiments are labeled with the same reference numerals, and description thereof will be omitted or simplified.

The flexible substrates 10 and 31 according to the above-described first and second embodiments can be mounted and implemented on a component. In the present embodiment, an optical module in which the flexible substrate 10 according to the first embodiment is implemented will be described below.

Specifically, an optical module 100 according to the present embodiment is a semiconductor laser module and has a laser light source 112, a wavelength locker 114, an optical modulator 116, a polarization combiner 118, and a termination substrate 140 inside a casing 110, as illustrated in FIG. 5. In order to clearly depict the optical connection relationship of the laser light source 112, the wavelength locker 114, the optical modulator 116, and the polarization combiner 118, FIG. 5 depicts dashed lines to represent the termination substrate 140 and a wiring substrate 138 for electrically connecting the optical modulator 116 to the termination substrate 140, which are arranged in a different height from the above-listed components.

The laser light source 112 is for generating a seed light L1 that is an origination of an output signal light. The wavelength locker 114 is for monitoring the output and the wavelength of the seed light L1 originated from the laser light source 112 and arranged adjacent to the light output part of the laser light source 112. The laser light source 112 has a laser diode, which is a semiconductor laser that launches the seed light L1, and a temperature adjustment mechanism for adjusting the temperature of the laser diode (for example, a thermoelectric element (Thermo-Electric Cooler (TEC)) such as a Peltier element). The wavelength of the seed light L1 is monitored by the wavelength locker 114, and temperature adjustment is performed by using a thermoelectric element in accordance with the wavelength of the monitored seed light L1 such that the output light from the laser diode has a desired wavelength. Note that the wavelength locker 114 may include another temperature adjustment mechanism (for example, a TEC) separately from the laser light source 112, and fine adjustment may be performed by using a thermoelectric element of the wavelength locker 114 so that the output light from the laser diode has a desired wavelength.

The optical modulator 116 is for modulating the seed light L1 input via the wavelength locker 114 and outputting the modulated seed light L1 and is arranged adjacent to the light output part of the wavelength locker 114. The optical modulator 116 outputs two signal lights L2a and L2b modulated by changing the optical phase of the seed light L1 and a local oscillator light (LO light) L3 branched from the seed light L1 and used for demodulation at an optical receiver. For example, when the phases of the signal light L2a and the signal light L2b are modulated by four values to perform optical polarization multiplexing, the signal light L2a and the signal light L2b together represent an eight-value state. Such a modulation scheme is referred to as Dual Polarization-Quadrature Phase Shift Keying (DP-QPSK) modulation. In FIG. 5, the optical modulator 116 having a U-shape optical waveguide whose incident end part and launching end part of a light are on the same end face is considered, and the signal light L2a, the signal light L2b, and the LO light L3 are launched from the same end face as the incident end face of the seed light L1.

In this case, the wavelength locker 114 may not necessarily be required to be arranged between the laser light source 112 and the optical modulator 116, and when a backward light of the laser light source 112 is used, the wavelength locker 114, the laser light source 112, and the optical modulator 116 may be arranged in this order, for example.

The optical modulator 116 used in an optical module of the present embodiment may be a semiconductor modulator, which may be formed by integrating semiconductor optical amplifiers (SOA) in a monolithic manner. The optical modulator 116 has a temperature adjustment mechanism for adjusting the temperature of the semiconductor modulator in a similar manner to the laser light source 112. A high frequency signal for modulation is input to the input side of the optical modulator 116 via a wiring substrate 128, and the termination substrate 140 is connected to the termination side of the optical modulator 116 via a multilayer substrate 134 and the wiring substrate 138.

The polarization combiner 118 is for combining (polarization-combining) the signal light L2a and the signal light L2b output from the optical modulator 116 to obtain a signal light L4 and is arranged adjacent to the modulated-light output part of the optical modulator 116. The polarization combiner 118 uses a ½-wavelength plate to polarize one of the polarized waves of the signal light L2a and the signal light L2b that are modulated and output by the optical modulator 116 and combines the polarized one with the other to output one signal light L4.

Note that signal lights having different polarized waves (for example, the signal light L2a that is a TM mode light and the signal light L2b that is a TE mode light) may be output from the optical modulator 116 and these signal lights may be polarization-combined in the polarization combiner 118.

The light output part of the polarization combiner 118 is optically coupled to a signal light output port 120 provided to the casing 110 and adapted to be able to output the signal light L4 to the outside. Further, an LO light output part of the optical modulator 116 is optically coupled to an LO light output port 122 provided to the casing 110 and adapted to be able to output the LO light L3 to the outside.

With optical paths from the laser light source 112 to the output ports 120 and 122 being arranged in the U-shape as illustrated in FIG. 5, the size of the entire optical module can be reduced.

The laser light source 112, the wavelength locker 114, the wiring substrate 128, and the termination substrate 140 are connected to a control unit and a power source (not depicted). The power source may include a high frequency power source, a direct current power source, or an alternating power source in accordance with the type of each component, and at least a part thereof may be formed of a battery. The control unit controls power supply from the power source to each component according to a user operation of the control unit or according to a program pre-stored in the control unit.

On one of the sidewall faces of the casing 110, a plurality of lead pins 130 are provided aligned in two lines in the longitudinal direction of the sidewall face. Each lead pin 130 is electrically connected to each unit of the optical module 100 in order to apply a drive voltage or input and output various signals. Each lead pin 130 is inserted through the corresponding through hole 22 of the flexible substrate 10 and fixed and electrically connected to the corresponding land 18 by the conductive fixing member 32. Note that the plurality of lead pins 130 are not necessarily required to be provided aligned in two lines and may be provided aligned in a plurality of lines in accordance with the number of lines of the plurality of corresponding lands of the flexible substrate to be mounted.

FIG. 6 illustrates a part of the configuration of the transceiver device 200 with the above-described optical module 100 illustrated in FIG. 5. As depicted, a transmitter area 204 on which a transmitter is mounted and a receiver area 206 on which a receiver is mounted are defined on the substrate 202. The transmitter area 204 and the receiver area 206 are regions longer in the longitudinal direction of the substrate 202, respectively, and are arranged adjacent to each other. Note that, in FIG. 6, a part of the configuration of the transmitter and the whole configuration of the receiver are omitted.

The optical module 100 used as the transmission module is mounted on the transmitter area 204 of the substrate 202. There is no sufficient space secured in the receiver area 206 side of the transmitter area 204. Thus, the optical module 100 is arranged such that the sidewall face of the casing 110 on which the lead pins 130 are provided is positioned in one of the outer circumference sides of the substrate 202 which is the opposite side of the receiver area 206.

In the optical module 100, the flexible substrate 10 is mounted on the side where the lead pins 130 are provided. The plurality of lands 18 and the through holes 22 are formed on the flexible substrate 10 correspondingly to the lead pins 130 of the optical module 100. Respective lead pins 130 of the optical module 100 are inserted through the corresponding through holes 22 of the flexible substrate 10 and fixed and electrically connected to the corresponding land 18 by the conductive fixing member 32.

One or a plurality of substrates such as wiring substrates (not shown) are provided above the substrate 202. The flexible substrate 10 is used for electrically connecting a substrate provided above the substrate 202 or other modules mounted on the substrate to the optical module 100.

The optical module 100 is used as a transmission module forming a transmitter in a transceiver device for optical communication as described above. In transceiver devices, there is a strong demand for reducing size and power consumption, and the size according to the CFP2 specification considered to be introduced for middle range optical communications is 80 mm×40 mm, and therefore an appropriate size of the transmission module may be half the size according to the CFP2 specification, namely, around 80 mm×20 mm. In practice, due to a space for a control substrate or routing of a fiber, it is desirable to suppress the size of the transmission module to around 25 mm×20 mm.

In such a transmission module where reduction in size is demanded, the location which can accommodate wirings for electrically connecting the transmission module to another substrate or the like is limited. Thus, in a transmission module, it is preferable to provide lead pins on a limited surface of the casing thereof. In this case, it is necessary to densely arrange many lead pins, which may require the lead pins to be arranged in two or more, namely, a plurality of lines.

Further, there is a similar issue in reducing size not only in the transmission module as described above but also in various optical modules.

As described above, in the flexible substrate 10, the lands 18 and the through holes 22 corresponding thereto can be densely formed. Therefore, even in the case of a plurality of lead pins 130 densely provided in the optical module 100, the flexible substrate 10 allows the corresponding land 18 to be fixed and electrically connected to each lead pin 130.

### Modified Embodiments

The present invention is not limited to the embodiments described above, and various modifications are possible.

For example, while the case where the plurality of lands 18 are formed in two lines of the first line LL1 and the second line LL2 has been described in the embodiments described above, the number of lines in which the plurality of lands 18 are formed is not limited thereto. The plurality of lands 18 can be formed aligned in three or more lines.

Further, while the case where the wirings 20a and 20b extend in the y-direction orthogonal to the x-direction with respect to the plurality of lands 18 formed aligned in two lines in the x-direction has been described in the embodiments described above, the extending direction of the wirings 20a and 20b is not limited thereto. The extending direction of the wirings 20a and 20b may be any direction as long as it intersects the x-direction that is the direction in which the plurality of lands 18 are aligned in a line.

Further, while the case where the through hole 22 penetrating a substrate is formed as a via in the embodiments described above as an example, the via is not limited thereto. The via may be not only a penetrating via but also a non-penetrating via and may be a non-penetrating via formed from an outer layer to an inner layer of a substrate, for example.

Further, an optical component on which the flexible substrate 10 is implemented is not limited to those in the embodiments described above. An optical module or the like to which space saving is required and which has many lead pins is particularly suitable as an optical component on which the flexible substrate 10 is implemented.

Further, while the case where the flexible substrate 10 is implemented on the optical module 100, which is an optical component, has been described as an example, the component to which the flexible substrate 10 is implemented is not limited to optical components. The component on which a flexible substrate in implemented may be various components other than optical components.

What is claimed is:

1. A flexible substrate comprising:
an insulating base member;
a plurality of lands formed aligned in a plurality of lines in a first direction on the base member; and
a plurality of wirings formed on the base member, extending in a second direction intersecting the first direction, and connected to the plurality of lands on each line of the plurality of lines,
wherein the plurality of wirings include a wiring extending between the lands aligned in the first direction, and
wherein each of the plurality of lands has a planar shape longer in the second direction.

2. The flexible substrate according to claim 1 further comprising a reinforcement plate that is provided to the base member and has an outer circumference surrounding a region in which the plurality of lands are formed.

3. The flexible substrate according to claim 1,
wherein a plurality of penetrating or non-penetrating vias are formed in the base member correspondingly to the plurality of lands, and
wherein each of the plurality of lands is formed around an opening of corresponding one of the plurality of vias.

4. The flexible substrate according to claim 3,
wherein each of the plurality of vias has a complete-circular cross section shape.

5. The flexible substrate according to claim 1,
wherein a pitch in the first direction of the plurality of lands is less than or equal to 0.8 mm.

6. The flexible substrate according to claim 1,
wherein the number of the plurality of lands is greater than or equal to 50.

7. An optical module in which a flexible substrate is mounted, the optical module comprising a plurality of lead pins provided aligned in a plurality of lines,
wherein the flexible substrate has
an insulating base member;
a plurality of lands formed aligned in a plurality of lines in a first direction on the base member, corresponding to the plurality of lead pins; and
a plurality of wirings formed on the base member, extending in a second direction intersecting the first direction, and connected to the plurality of lands on each line of the plurality of lines,
wherein the plurality of wirings include a wiring extending between the lands aligned in the first direction,
wherein each of the plurality of lands has a planar shape longer in the second direction,
wherein a plurality of vias are formed in the base member correspondingly to the plurality of lands, and
wherein each of the plurality of lands is formed around an opening of corresponding one of the plurality of vias, and
wherein each of the plurality of lead pins are inserted through corresponding one of the plurality of vias and fixed and electrically connected to corresponding one of the plurality of lands.
